(19) United States
(12) Patent Application Publication
(10) Pub. No.: US 2013/0176033 A1
(43) Pub. Date: Jul. 11, 2013

(54) BATTERY PROTECTION DEVICE AND TESTING METHOD THEREOF

(71) Applicant: Tai-Hung Chen, Hsinchu County (TW)

(72) Inventor: Tai-Hung Chen, Hsinchu County (TW)

(21) Appl. No.: 13/556,220

(22) Filed: Jul. 24, 2012

(30) Foreign Application Priority Data
Jan. 5, 2012 (TW) 101100452

(51) Int. Cl. G01R 31/36

(52) U.S. Cl. 324/433

(57) ABSTRACT

A battery protection device is disclosed in the present invention. The battery protection device includes a voltage detecting circuit and a controller coupled to the voltage detecting circuit. The voltage detecting circuit includes a testing unit, a switch coupled to the testing unit, a comparator coupled to an input voltage source and the switch for comparing a value of the input voltage source with a value of the switch, and a determining unit coupled to the comparator for outputting a determining signal when receiving a prompting signal from the comparator. The controller is for receiving an external testing command to switch the switch from a reference voltage source from a testing voltage source via the testing unit, so as to inspect whether the voltage detecting circuit is normal by the determining signal of the determining unit.

### BACKGROUND OF THE INVENTION

1. Field of the Invention

The present invention relates to a battery protection device, and more particularly, to a battery protection device capable of executing a functional test of a voltage detecting circuit by the user and a testing method thereof.

2. Description of the Prior Art

A voltage protection device is a protection circuit, and can be actuated when operation of the battery is abnormal. The battery is composed of a plurality of electrical cells. The electrical cell may generate overcurrent when its operating voltage is interfered by error or high temperature, and the battery is damaged and lost usability. Therefore, the voltage protection device is a necessary circuit for the battery protection. However, a conventional voltage protection device is tested during manufacturing procedures, to ensure whether the protecting function is normal. For example, the conventional testing procedure utilizes a specific tool to raise voltage values of the electrical cells over than a reference voltage source, so as to inspect whether the voltage protection device is normal or not. When the battery is sold to the consumer, the consumer can not execute the functional test of the voltage protection device, and fails to choose the normal battery for preventing danger. Thus, design of a voltage protection device capable of executing the functional test by the consumer is an important issue in the battery industry.

### SUMMARY OF THE INVENTION

The present invention provides a battery protection device capable of executing a functional test of a voltage detecting circuit by the user and a testing method thereof for solving above drawbacks.

According to the claimed invention, a battery protection device includes a voltage detecting circuit, and a controller coupled to the voltage detecting circuit. The voltage detecting circuit includes a testing unit, a switch coupled to the testing unit, a comparator coupled to an input voltage source and the switch, and a determining unit coupled to the comparator. The switch is switched to a reference voltage source or a testing voltage source according to a controlling signal outputted from the testing unit. The comparator is for comparing a value of the input voltage source with a value of the switch. The determining unit is for outputting a determining signal when receiving a prompting signal outputted from the comparator. The controller is for receiving an external testing command to switch the switch to the testing voltage source by the testing unit, so as to inspect whether the voltage detecting circuit is normal by the determining signal outputted from the determining unit.

According to the claimed invention, a testing method of a battery protection device, the testing method includes receiving an external testing command to actuate a testing mode of a voltage detecting circuit; switching a switch from a reference voltage source to a testing voltage source; comparing a value of an input voltage source with a value of the testing voltage source and outputting a prompting signal according to comparison by a comparator; outputting a corresponding determining signal according to the prompting signal by a determining unit; and inspecting whether the voltage detecting circuit is normal according to the determining signal by a controller.

The present invention can utilize the controller to actuate the functional test of the battery protection device according to user's actual demand, so as to ensure that the voltage detecting circuit is normal, and to prevent the battery protection device from failure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a battery protection device according to an embodiment of the present invention.

FIG. 2 is a flow chart of a testing method of the battery protection device according to the embodiment of the present invention.

### DETAILED DESCRIPTION

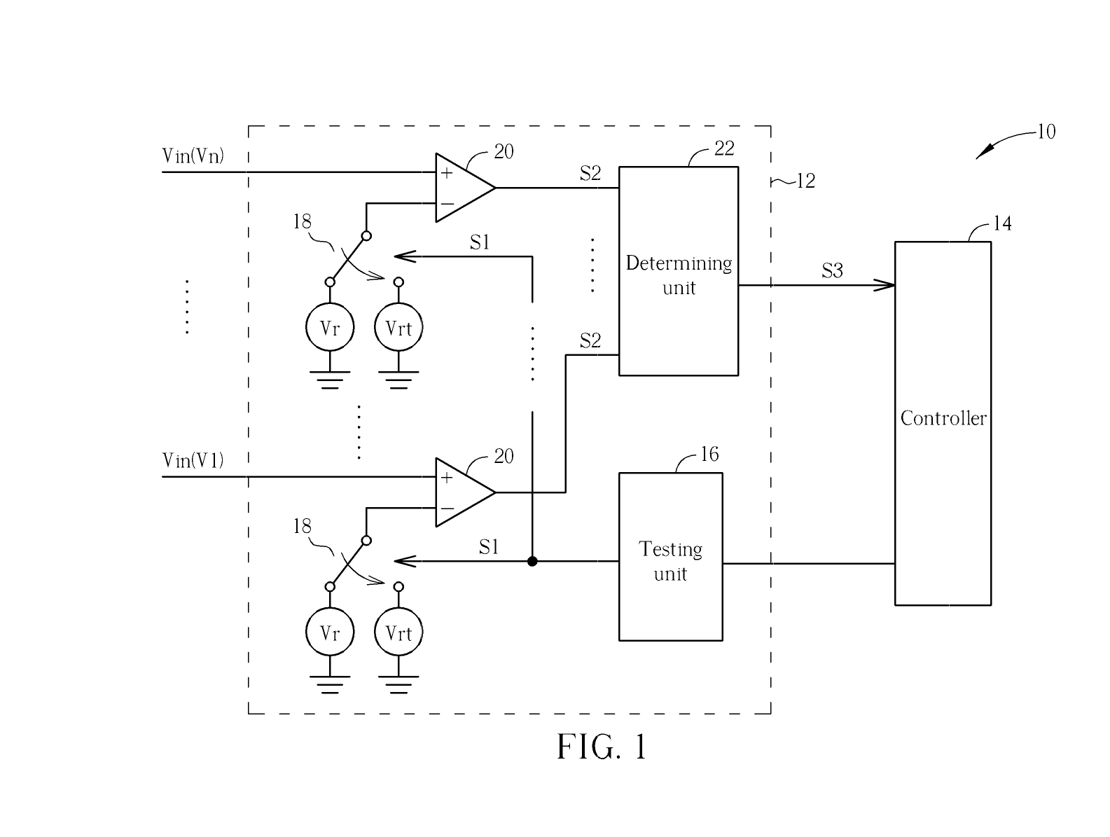

Please refer to FIG. 1. FIG. 1 is a functional block diagram of a battery protection device 10 according to an embodiment of the present invention. The battery protection device 10 is utilized to detect whether an output voltage of a battery is normal or abnormal, so as to prevent the battery from damage. For example, the battery may be damaged by overcurrent. The battery protection device 10 includes a voltage detecting circuit 12 and a controller 14. The controller 14 is coupled to the voltage detecting circuit 12 for receiving an external testing command, so as to drive the voltage detecting circuit 12 into a testing mode. The controller 14 can be a microcontroller (MCU), a Programmable Array Logic (PAL), and so on. The voltage detecting circuit 12 includes a testing unit 16, at least one switch 18, at least one comparator 20 and a determining unit 22. Generally, the battery can be composed of a plurality of electrical cells, and output voltages of the plurality of electrical cells (such as n electrical cells) can respectively be V1˜Vn, so the voltage detecting circuit 12 can substantially include a plurality of switches 18 (such as n switches 18) and a plurality of comparators 20 (such as n comparators 20). Thus, each electrical cell can be coupled to the corresponding switch 18 and the corresponding comparator 20.

In addition, the plurality of switches 18 can be respectively coupled to the testing unit 16, and can be switched to a reference voltage source Vr or a testing voltage source Vrt according to a controlling signal S1 outputted from the testing unit 16. Variation of the testing voltage source Vrt can be predetermined. The functional test is meaningless as the testing voltage source Vrt is close to the reference voltage source Vr. Accuracy of the functional test can be affected by error as the testing voltage source Vrt is too smaller than the reference voltage source Vr. For example, ½Vr≦Vrt≦⅔Vr. A positive input terminal of each comparator 20 can be coupled to a corresponding input voltage source Vin (one of V1 to Vn), a negative input terminal of each comparator 20 can be coupled to the corresponding switch 18, and an output terminal of each comparator 20 can be coupled to the determining unit 22. The comparator 20 can compare the value of the input voltage source Vin with the value of the switch 18, and output a high potential signal when the value of the input voltage source Vin is substantially greater than the value of the switch 18. The determining unit 22 can be coupled to the output terminals of the comparators 20. The determining unit 22 can output a corresponding determining signal S3 to the controller 14 when receiving a prompting signal S2 outputted from each comparator 20, so that the controller 14 can inspect whether the voltage detecting circuit 12 is normal or abnormal according to the determining signal S3 from the determining unit 22.

For example, the voltage detecting circuit 12 can detect whether the plurality of input voltage sources Vin is abnormal when the battery works. When the plurality of comparators 20 detects the value of at least one input voltage source Vin is greater than the value of the reference voltage source Vr, the determining unit 22 can receive the prompting signal S2 (the high potential signal) outputted from the corresponding comparator 20 coupled to the above-mentioned abnormal input voltage source Vin, and the controller 14 can read the determining signal S3 from the determining unit 22 to actuate an external protection circuit, such as a step-down circuit or a voltage control switch. Besides, the controller 14 can utilize the testing unit 16 to switch each switch 18 from the reference voltage source Vr to the testing voltage source Vrt, so as to detect function of the voltage detecting circuit 12 for battery safety. In the testing mode, the determining unit 22 can receive the plurality of prompting signals S2 (the plurality of high potential signals) outputted from the plurality of comparators 20 when elements of the voltage detecting circuit 12 are usable, so the controller 14 can confirm that the voltage detecting circuit 12 is normal according to the determining signal S3 outputted from the determining unit 22, and then finish reliability test of the battery protection device 10.

Furthermore, the negative input terminals of the comparators 20 are switched from the testing voltage source Vrt to the reference voltage source Vr after the reliability test of the battery protection device 10 has finished, so that the voltage detecting circuit 12 can be transformed from the testing mode to an operating mode. Therefore, the testing unit 16 can selectively include a timer (or other equivalent components). When the testing mode of the voltage detecting circuit 12 is actuated, the timer can automatically switch the plurality of switches 18 from the testing voltage source Vrt to the reference voltage source Vr after a predetermined duration (generally, the predetermined duration can be slightly greater than execution period of the testing mode), so as to recover the voltage detecting circuit 12 to the common operating mode.

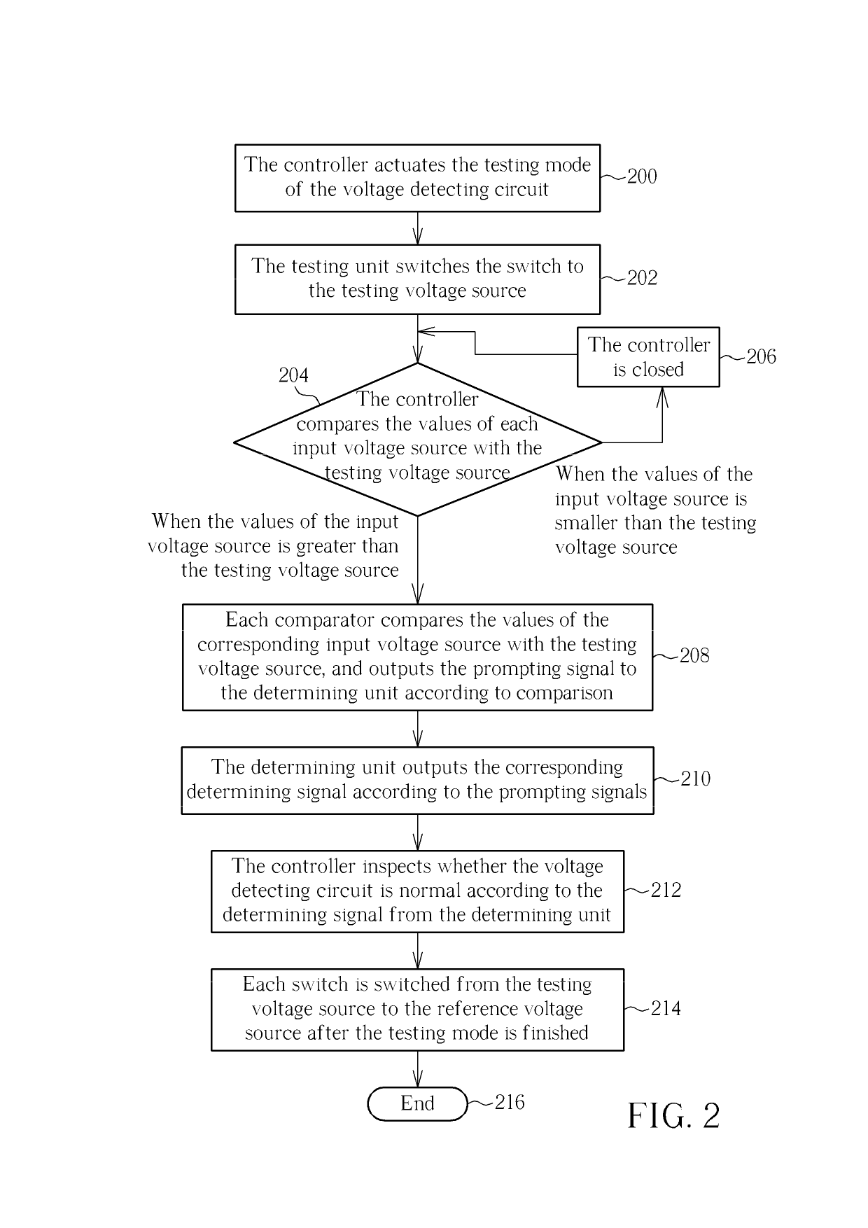

Please refer to FIG. 2. FIG. 2 is a flow chart of a testing method of the battery protection device 10 according to the embodiment of the present invention. The testing method includes following steps:

Step 200: The controller 14 receives the external testing command to actuate the testing mode of the voltage detecting circuit 12.

Step 202: The testing unit 16 switches the plurality of switches 18 from the reference voltage source Vr to the testing voltage source Vrt, and the value of the testing voltage source Vrt can be substantially smaller than the value of the reference voltage source Vr.

Step 204: The controller 14 compares the value of each input voltage source Vin with the value of the testing voltage source Vrt. Execute step 206 when the value of the input voltage source Vin is smaller than the value of the testing voltage source Vrt; Execute step 208 when the value of the input voltage source Vin is greater than the value of the testing voltage source Vrt.

Step 206: The controller 14 is closed for a predetermined period, and the input voltage source Vin can be charged during the predetermined period. Then execute step 204.

Step 208: Each comparator 20 compares the value of the corresponding input voltage source Vin with the value of the testing voltage source Vrt, and outputs the prompting signal S2 to the determining unit 22 according to comparison. Then execute step 210.

Step 210: The determining unit 22 outputs the corresponding determining signal S3 according to the plurality of prompting signals S2. Then execute step 212.

Step 212: The controller 14 inspects whether the voltage detecting circuit 12 is normal according to the determining signal S3 from the determining unit 22. Then execute step 214.

Step 214: Each switch 18 is switched from the testing voltage source Vrt to the reference voltage source Vr after the testing mode is finished, so as to recover the voltage detecting circuit 12 to the common operating mode.

Step 216: End.

Detail description is introduced as following. When the voltage detecting circuit 12 is under the operating mode, the plurality of switches 18 can be respectively coupled to the reference voltage source Vr. Each comparator 20 can compare the value of the corresponding input voltage source Vin with the value of the reference voltage source Vr, so as to actuate the external protection circuit when the value of the input voltage source Vin is abnormal for preventing the battery protection device 10 from damage by overcurrent. The controller 14 can input the external testing command to the testing unit 16 of the voltage detecting circuit 12 to inspect whether the voltage detecting circuit 12 is normal. The plurality of switches 18 can be driven by the controlling signal S1 from the testing unit 16 to switch from the reference voltage source Vr to the testing voltage source Vrt. Then, the controller 14 compares the values of the input voltage sources Vin (such as V1˜Vn) with the value of the testing voltage source Vrt. The controller 14 can be closed for the predetermined period when the value of the input voltage source Vin is substantially smaller the value of the testing voltage source Vrt, and the abnormal input voltage source Vin can be charged during the predetermined period. After the controller 14 inspects that the abnormal input voltage source Vin is fully charged, and the values of the plurality of input voltage sources Vin is completely greater than the value of the testing voltage source Vrt, the voltage detecting circuit 12 continues the testing mode.

When verification of the values of the input voltage sources Vin and the value of the testing voltage source Vrt is finished by the controller 14, each comparator 20 can compare the value of the corresponding input voltage source Vin with the value of the testing voltage source Vrt. Because the value of the testing voltage source Vrt is smaller than the value of the reference voltage source Vr, the output terminal of the comparator 20 can output the prompting signal S2 (the high potential signal) to the determining unit 22 when function of the comparator 20 is normal. When the determining unit 22 receives the plurality of prompting signals S2 (the high potential signals) and outputs the corresponding determining signal S3 to the controller 14, the controller 14 can confirm that the voltage detecting circuit 12 is normal. In addition, the controller 14 can confirm that the voltage detecting circuit 12 is abnormal according to the determining signal S3 from the determining unit 22 when an amount of the prompting signals S2 received by the determining unit 22 is smaller than n, which means at least one components (the switch 18, the comparator 20, the determining unit 22 and the input voltage source Vin) is not usable, so as to warn a user against damage of the voltage detecting circuit 12. Final, the testing unit 16 can utilize the timer or other equivalent components to automatically switch the plurality of switches 18 to the reference voltage source Vr after the predetermined duration (over than the execution period of the testing mode), so the voltage detecting circuit 12 can recover to the initial operating mode from the testing mode.

In conclusion, the battery protection device of the present invention can utilize the controller to execute the functional test of the voltage detecting circuit by the user (the consumer). The voltage detecting circuit enters the testing mode by receiving the external command, and the testing unit can drive the plurality of switches to respectively switch the negative input terminals of the comparators to be coupled to the testing voltage source. The value of the testing voltage source can be substantially smaller than the value of the reference voltage source. Therefore, each comparator can compare the values read by its positive input terminal and its negative input terminal, and output the high potential signal to the determining unit via the output terminal. The determining unit outputs the corresponding determining signal to the controller when receiving the prompting signals (the high potential signals) from the plurality of comparators. Final, the controller can read the determining signal to inspect that the value of each input voltage source is greater than the value of the testing voltage source and the elements of the voltage detecting circuit are usable, so as to confirm that protection of the voltage detecting circuit is normal. The present invention provides the battery protection device capable of executing the functional test of the voltage detecting circuit by the controller according to user's demand.

Comparing to the prior art, the present invention can utilize the controller to actuate the functional test of the battery protection device according to user's actual demand, so as to ensure that the voltage detecting circuit is normal, and to prevent the battery protection device from failure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A battery protection device comprising:
a voltage detecting circuit comprising:
a testing unit;
a switch coupled to the testing unit, the switch being switched to a reference voltage source or a testing voltage source according to a controlling signal outputted from the testing unit;
a comparator coupled to an input voltage source and the switch for comparing a value of the input voltage source with a value of the switch; and
a determining unit coupled to the comparator for outputting a determining signal when receiving a prompting signal outputted from the comparator; and
a controller coupled to the voltage detecting circuit for receiving an external testing command to switch the switch to the testing voltage source by the testing unit, so as to inspect whether the voltage detecting circuit is normal by the determining signal outputted from the determining unit.

2. The battery protection device of claim 1, wherein the determining unit outputs the determining signal to actuate an external protection circuit via the controller.

3. The battery protection device of claim 1, wherein the controller further compares the value of the input voltage source with a value of the testing voltage source.

4. The battery protection device of claim 3, wherein the controller inspects whether the voltage detecting circuit is normal when the value of the input voltage source is substantially greater than the value of the testing voltage source.

5. The battery protection device of claim 3, wherein the controller is closed for a predetermined period when the value of the input voltage source is substantially smaller than the value of the testing voltage source, and starts to compare the value of the input voltage source with the value of the testing voltage source after the predetermined period.

6. The battery protection device of claim 5, wherein the input voltage source is charged during the predetermined period.

7. The battery protection device of claim 1, wherein the voltage detecting circuit further comprises a plurality of switches respectively coupled to the testing unit, each switch is switched to the reference voltage source or the testing voltage source according to the controlling signal outputted from the testing unit, the voltage detecting circuit further comprises a plurality of comparators respectively coupled to a corresponding input voltage source and the corresponding switch, the controller further inspects whether the voltage detecting circuit is normal when the determining unit receives the prompting signals outputted from the plurality of comparators.

8. The battery protection device of claim 1, wherein the testing unit comprises a timer, the timer switches the switch from the testing voltage source to the reference voltage source after a predetermined duration.

9. A testing method of a battery protection device, the testing method comprises:
receiving an external testing command to actuate a testing mode of a voltage detecting circuit;
switching a switch from a reference voltage source to a testing voltage source;
comparing a value of an input voltage source with a value of the testing voltage source and outputting a prompting signal according to comparison by a comparator;
outputting a corresponding determining signal according to the prompting signal by a determining unit; and
inspecting whether the voltage detecting circuit is normal according to the determining signal by a controller.

10. The testing method of claim 9, wherein inspecting whether the voltage detecting circuit is normal according to the determining signal by the controller comprises:
confirming that the voltage detecting circuit is normal when the value of the input voltage source is substantially greater than the value of the testing voltage source and the prompting signal is a high potential signal.

11. The testing method of claim 9, wherein the testing method further comprises:
switching a plurality of switches respectively from the reference voltage source to the testing voltage source; and
comparing the value of the corresponding input voltage source and the value of the testing voltage source and outputting the plurality of prompting signals according to comparisons by a plurality of comparators.

12. The testing method of claim 11, further comprising:
confirming that the voltage detecting circuit is normal when the plurality of prompting signals is high potential signals.

13. The testing method of claim 11, further comprising:
confirming that the voltage detecting circuit is abnormal when at least one of the prompting signals is not a high potential signal.

14. The testing method of claim 9, further comprising:
comparing the value of the input voltage source and the value of the testing voltage source and executing corresponding operation according to the comparison by the controller.

15. The testing method of claim 14, wherein the controller is closed for a predetermined period when the value of the input voltage source is substantially smaller than the value of the testing voltage source, and starts to compare the value of the input voltage source with the value of the testing voltage source after the predetermined period.

16. The testing method of claim 15, wherein the input voltage source is charged during the predetermined period.

17. The testing method of claim 9, further comprising:
switching the switch from the testing voltage source to the reference voltage source when the testing mode of the voltage detecting circuit is finished.

18. The testing method of claim 17, further comprising:
switching the switch from the testing voltage source to the reference voltage source by a timer after a predetermined duration.
